(19) United States
(12) Patent Application Publication
(10) Pub. No.: US 2024/0004303 A1
(43) Pub. Date: Jan. 4, 2024

(54) PHOTORESIST REMOVER COMPOSITIONS

(71) Applicant: Merck Patent GmbH, Darmstadt (DE)

(72) Inventors: Hengpeng WU, Hillsborough, NJ (US); David RENNIE, Bethlehem, PA (US)

(21) Appl. No.: 18/251,922

(22) PCT Filed: Dec. 13, 2021
(86) PCT No.: PCT/EP2021/085370

§ 371 Date: May 5, 2023

Related U.S. Application Data
(60) Provisional application No. 63/125,666, filed on Dec. 15, 2020.

(51) Int. Cl. G03F 7/42; C11D 3/43; C11D 3/34; C11D 11/00

(52) U.S. Cl. CPC G03F 7/426; C11D 3/43; C11D 3/3418; C11D 11/0023

(57) ABSTRACT

The present invention relates to a composition including at least one sulfosalicylic acid having structure (I), or its hydrate, and mixtures thereof and a sulfosalicylic acid having structure (I), or its hydrate, a primary solvent selected from acetone, and methyl ethyl ketone, or a mixture of these solvents, an optionally a secondary solvent which is a glycolic derivative, or a mixture of at least two glycolic derivatives, and an optional surfactant.

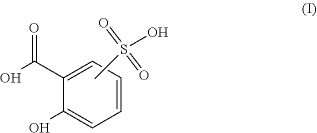

### FIELD OF INVENTION

The present invention relates to compositions of a low pKₐ remover solution consisting of a sulfonic acid selected from a sulfosalicylic acids having structure (I), a primary solvent selected either from acetone, and methyl ethyl ketone, or a mixture of this primary solvent with an optional secondary solvent which is a glycolic derivative.

### BACKGROUND

This invention relates to a chemical stripper composition that removes cross-linked polymer coatings using inventive remover compositions which do not promote corrosion of metal substrates, but which unexpectedly also do not require the presence of metal protecting chelating compounds or polymers of charge complexing character to prevent significant corrosion.

Materials removed by these inventive formulations include positive tone and negative-tone chemically amplified (e.g., epoxy) and acid-catalyzed photoimageable coatings. Many commercialized strippers for microelectronic coatings do not perform sufficiently to meet minimum manufacturing requirements. The invention provides a commercial framework for removal products for cross-linked systems that respond in acidic media without the harmful etching and damaging effects commonly observed on devices that contain metals such as copper or tin, but at the same time do not contain metal chelating compound that may deleteriously form particulate matter during the removing/stripping process.

For various processed conditions, up to and including hard-baking, or otherwise referred to as full-cure, the composition will remove and dissolve chemically amplified reacted compounds within minutes without damaging effects to sensitive metals such as copper or tin, using conventional immersion conditions at elevated temperatures. Such full-cure coatings are found to be resistant to conventional organic strippers that commonly comprise alkaline ingredients as exemplified in U.S. Pat. No. 6,551,973. When using these conventional strippers, no dissolution occurs. Instead, these conventional alkaline strippers are observed to remove the coating by mechanisms of lifting or breaking-up into pieces. This lift-off mechanism generates incomplete removal from complex three-dimensional topographies as commonly seen in microelectromechanical systems (MEMS) devices. Un-dissolved material will produce particles that are circulated throughout the bath, causing re-deposition of the un-dissolved pieces onto other areas of the device. Such contamination that occurs onto these tiny, computer controlled, gears, sensors, springs, pumps, and related micro or nano-scale fixtures results in contamination and device failure. It is an object of this invention to achieve full dissolving of the unwanted polymer material during the given stripping and removal period.

Some low pKₐ systems that remove crosslinked coatings, do so by complete dissolution, rather than lift-off. However, these materials contain metal corrosion inhibitors which unexpectedly causes a particulate problem, due to the precipitation of these inhibitor components during the removal process. These corrosion inhibitors are metal complexing additives which are added to prevent corrosion of metal substrates, by the low pKₐ remover by complexing with metal substrates, during the removal process. Examples of such corrosion inhibitors are small molecules, oligomers or polymers containing a moiety of the enol variety, for instance, containing an unsaturated carbon chain adjacent to alcohol functionality. Representative enol inhibitors include fumaric, maleic, and phthalic acids. More specific examples of inhibitors are those of the rosin variety; these are, for instance, fumarated rosins. The particles formed by metal corrosion inhibitor in low pKₐ removers, may deposit unto other areas of the device, deleteriously affecting the performance of the final device. Non-limiting examples of such low pKₐ remover systems containing such metal corrosion inhibitors are described in WO2016/142507.

During the manufacture of these microcircuits or micro-devices, various inorganic substrates such as single and polycrystalline silicon, hybrid semiconductors such as gallium arsenide, and metals, are coated with an organic coating (“photoresist” or “resist”) which forms a resistant framework of permanent or temporary design and exhibits a pattern after undergoing a photolithographic process. The photoresist may be utilized to insulate conductors or protect selected areas of the substrate surface, such as silicon, silicon dioxide, or aluminum, from the action of chemicals in both wet (chemical) and dry (plasma) forms. In the case of the material being utilized as a photoresist, exposed areas of the substrate may carry out a desired etch (removal) or deposition (addition) process. Following completion of this operation and after subsequent rinsing or conditioning, it is necessary that the resist and any application post-etch residue be removed to permit essential finishing operations. Upon removal of the photoresist, specific micro-etched or deposited patterns are left behind. The masking and patterning processes are repeated several times to produce layered arrangements that comprise the art of the final device. Each step requires complete resist stripping and dissolving to ensure that the final form device is produced at relatively high yields and performs satisfactorily without particle formation and with complete dissolution of the photoresist film, instead of just delaminate it. Depending of which type photoresist is employed, these materials may contain additives such as photo-active compounds (e.g., DNQ), photo-acid generators (PAG), and photoradical generators, which may be prone to particle formation. The deposition of any particles during this process into active area deleteriously affects both the yield and performance of devices. Also, another problem to solve is to enable very fast photoresist removal with complete dissolution in photoresist used for metal lift-off application. This is because metal covers the whole photoresist patterns with some areas having few penetrating points for remover chemistry. Because of this there is a need for remover solutions to dissolve photoresist quickly to enable fast metal lift-off.

### SUMMARY OF THE INVENTION

The current invention is an improved stripping composition that will remove a wide range of different pattered photoresist film including ones formed from different types of both negative and positive resist systems and can within 2 min or less remove thick photoresist films even when these are underneath a metal film. Of these different types, examples are resists which are imagable by visible light, broadband i-line, g-line, h-line, UV, 248 nm, 193 nm, 193 nm immersion, deep UV, EUV, electron or e-beam. Specifically, the current improved stripping composition, gives fast complete dissolution in 2 minutes or less of all components in a thick photoresist film. Further, this photoresist removal from substrates occurs without attack to underlying exposed silver, copper and/or tin as well as other metals, without the use of metal corrosion inhibitor additives as such additives are prone to also promote particle formation during the removal of the resist pattern.

The current inventive remover compositions impart these advantageous properties by very quickly and completely dissolving the photoresist pattern, from patterns formed from many different types of resist usually within 30 to 20 seconds or less for photoresist films having a thickens of about 10 μm to about 100 μm, depending on the thickness, pattern type and photoresist type. This removal is affected without forming lifted-off resist film or particles resulting from either resins or additives in the remover and without corroding metal substrates the photoresist film is coated on. When such photoresist film are underneath a metal layer which inhibits access of the remover to the photoresist film, the current inventive formulation can remove such film about 2 to about 10 times faster than other removers in as little as about 2 minutes or less depending on the bimetallic structures geometry. At the same time, unexpectedly, this remover composition does not require the presence of any inhibitor additive to suppress corrosion (no significant corrosion), and do not give corrosion of metal substrate such as silver, copper, tin and the like and have no issue with the precipitation of metal corrosion inhibitor during the removal process using these inventive remover compositions. These inventive remover compositions, and processes of use thereof, have been found to be especially useful in the manufacture of semiconductor wafers, MEMS devices, and displays. In summary these inventive remover compositions have the following advantages, (1) no need for anti-corrosion agents; (2) dissolve photoresist film instead of just delaminate it, (3) very fast dissolution rates even when underneath a metal layer. Thus, these inventive remover compositions enable fast photoresist removing in photoresist used for metal lift-off application. As a non-limiting example of such a photoresist are photoresist which a negative i-line and broadband photoresist which comprise a Novolak resin.

In one of its aspects, the present invention relates to a composition consisting essentially of either at least one sulfosalicylic acids having structure (I), its hydrate, or a mixture of this sulfosalicylic acid and its hydrate; a primary solvent selected from acetone, and methyl ethyl ketone, or a mixture of these solvents, an optionally secondary solvent which is a glycolic derivative, or a mixture of at least two glycolic derivatives, and an optional surfactant.

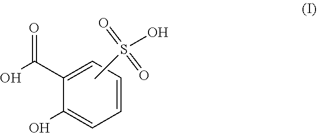

In another aspect, the present invention relates to using the above compositions to remove a photoresist film from a substrate.

### DETAILED DESCRIPTION

It is to be understood that both the foregoing general description and the following detailed description are illustrative and explanatory, and are not restrictive of the subject matter, as claimed. In this application, the use of the singular includes the plural, the word “a” or “an” means “at least one”, and the use of “or” means “and/or”, unless specifically stated otherwise. Furthermore, the use of the term “including”, as well as other forms such as “includes” and “included”, is not limiting. Also, terms such as “element” or “component” encompass both elements and components comprising one unit and elements or components that comprise more than one unit, unless specifically stated otherwise. As used herein, the conjunction “and” is intended to be inclusive and the conjunction “or” is not intended to be exclusive unless otherwise indicated. For example, the phrase “or, alternatively” is intended to be exclusive. As used herein, the term “and/or” refers to any combination of the foregoing elements including using a single element.

The term (meth)acrylate is a term which embodies in one term both acrylate and methacrylate.

The terms “stripper” and “remover” are synonymous.

The expression “consisting essentially of” has the meaning that the constituents form at least 90 wt %, more preferably at least 95 wt %, most preferably at least 99 wt % of the composition.

The term “essentially” is intended to mean that no further components similar to the listed components are present in the composition.

According to one embodiment of the invention, the term “consisting essentially of” can be replaced by “consisting of” thereby allowing for no further components in the composition.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature citations and similar materials defines a term in a manner that contradicts the definition of that term in this application, this application controls.

The term alkyl refers to a C-1 to C-8 linear alkyl, a C-2 to C-9 branched alkyl and a C-5 to C-8 cyclic alkyl

The term alkyl carboxylate refers to the moiety alkyl-(C═O)—O— [alkylCO₂—].

When referring to compositions in terms of wt %, it is understood that in no event shall the wt % of all components, including non-essential components, such as impurities, add to more than 100 wt %. The composition of all essential components may add up to less than 100 wt % in those instances wherein the composition contains some small amount of a non-essential contaminants or impurities. Otherwise, if no significant non-essential impurity component is present, it is understood that the composition of all essential components will essentially add up to 100 wt %.

The term glycolic derivative used herein refers to alkylenediols, oligo(alkyleneoxyalkylene) diols [HO-(alkylene-O-alkylene-O)ₙ—H] (n=1 to 4), monoalkyl and dialkyl ethers of alkylenediols, oligo(alkyleneoxyalkylene) diols [HO-(alkylene-O-alkylene-O)ₙ—H] (n=1 to 4), mono and dialkylcarboxylate of alkylenediols, oligo(alkyleneoxyalkylene) diols [HO-(alkylene-O-alkylene-O)ₙ—H] (n=1 to 4), oligo(alkyleneoxyalkylene) diols [HO-(alkylene-O-alkylene-O)ₙ—H] (n=1 to 4) in which one hydroxy is functionalized as an alkyl ether and the other hydroxy is functionalized by an alkylcarboxylate,

In one of its aspects, the present invention relates to a composition consisting essentially of
a) one of a sulfosalicylic acids having structure (I), its hydrate, or a mixture of this sulfosalicylic acid and its hydrate;
b) a primary solvent selected from acetone, and methyl ethyl ketone, or a mixture of these solvents,
c) an optional secondary solvent which is a glycolic derivative, or a mixture of at least two glycolic derivatives, and
d) an optional surfactant, respectively, described herein, in varying concentration.
   In this embodiment, the combined amounts of the above components do not have to equal 100% by weight (e.g., the constituents can form at least 90 wt %, more preferably at least 95 wt %, more preferably at least 99 wt %, more preferably at least 99.5 wt %, most preferably at least 99.9 wt %),), and can include other ingredients that do not materially affect the performance of the remover. In another aspect of this embodiment the composition consists of components a), b), c) and d).

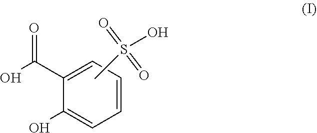

Some embodiments of the inventive compositions, consist essentially of,
a) one of at least one sulfosalicylic acid having structure (I), its hydrate, or a mixture of this sulfosalicylic acid and its hydrate;
b) a primary solvent selected from acetone, and methyl ethyl ketone, or a mixture of these solvents; and
c) a secondary solvent which is a glycolic derivative, or a mixture of at least two glycolic derivatives. described herein, in varying concentration.
   In this embodiment, the combined amounts of the above components cannot exceed 100% by weight, do not have to equal 100% by weight (e.g., the constituents can form at least 90 wt %, more preferably at least 95 wt %, more preferably at least 99 wt % of the composition, more preferably at least 99.5 wt %, most preferably at least 99.9 wt %), and can include other ingredients that do not material affect the performance of the remover. In another aspect of this embodiment the inventive composition consists of the above component a), b) and c).

In one of its aspects, the present invention relates to a composition consisting essentially of
a) one of at least one sulfosalicylic acids having structure (I), its hydrate, or a mixture of this sulfosalicylic acid and its hydrate;
b) a primary solvent selected from acetone, and methyl ethyl ketone, or a mixture of these solvents; and
c) and a surfactant.
   In this embodiment, the combined amounts of the components a), b) and c) cannot exceed 100% by weight but do not have to equal 100% by weight. Other materials that do not affect the performance of this remover material can be present if these materials do not affect the performance of the remover formulations. In one embodiment components a), b), and c) form at least 90 wt %, more preferably at least 95 wt %, more preferably at least 99 wt % of the composition, more preferably at least 99.5 wt %, most preferably at least 99.9 wt %).

In one of its aspects, the present invention relates to a composition consisting of
a) one of at least one sulfosalicylic acids having structure (I), its hydrate, or a mixture of this sulfosalicylic acid and its hydrate;
b) a primary solvent selected from acetone, and methyl ethyl ketone, or a mixture of these solvents; and
c) and a surfactant.
   In this embodiment, the combined amounts of the above components 100% by weight and not other materials are significantly present.

In one of its aspects, the present invention relates to a composition consisting of,
a) one of at least one sulfosalicylic acids having structure (I), its hydrate, or a mixture of this sulfosalicylic acid and its hydrate;
b) a primary solvent selected from acetone, and methyl ethyl ketone, or a mixture of these solvents.
   In this embodiment, the combined amounts of the above components 100% by weight and not other materials are significantly present.

In one of its aspects, the present invention relates to a composition consisting essentially of,
a) one of at least one sulfosalicylic acids having structure (I), its hydrate, or a mixture of this sulfosalicylic acid and its hydrate;
b) a primary solvent selected from acetone, and methyl ethyl ketone, or a mixture of these solvents.

In this embodiment, the combined amounts of the components a), and b) cannot exceed 100% by weight but do not have to equal 100% by weight. Other materials that do not affect the performance of this remover material can be present if these materials do not affect the performance of the remover formulations. In one embodiment components a), and b), form at least 90 wt %, more preferably at least 95 wt %, more preferably at least 99 wt % of the composition, more preferably at least 99.5 wt %, most preferably at least 99.9 wt %).

In embodiments of the composition described herein which have as one of its components a sulfosalicylic acid of structure (I) (or its hydrate), more specific embodiments of these, are selected from ones having structures (Ia), (Ib), (Ic), (Id) (or its hydrate) and mixtures thereof.

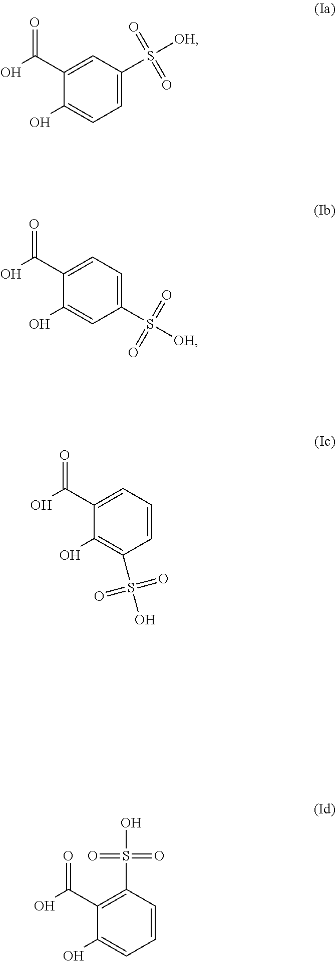 [SMILES: O=C(O)c1cc(S(=O)(=O)O)ccc1O ; O=C(O)c1ccc(S(=O)(=O)O)cc1O ; O=C(O)c1cccc(S(=O)(=O)O)c1O ; O=C(O)c1c(O)cccc1S(=O)(=O)O]

In some embodiments the sulfosalicylic acid of structure (I) (or its hydrate) is a compound having structure (Ia) (or its hydrate).

In some embodiments the sulfosalicylic acid of structure (I) (or its hydrate) is a compound having structure (Ib) (or its hydrate).

In some embodiments the sulfosalicylic acid of structure (I) (or its hydrate) is a compound having structure (Ic) (or its hydrate).

In some embodiments the sulfosalicylic acid of structure (I) (or its hydrate) is a compound having structure (Id) (or its hydrate).

In another embodiment of any of the above aspects of this composition, the sulfosalicylic acid component, it is one having structure (I) (or is hydrate) and it has a wt % loading in the total wt of the solution ranging from about 0.5 wt % to about 10 wt %. In another aspect of this embodiment the wt % loading of this acid is from about 0.75 wt % to about 7.00 wt %. In another aspect of this embodiment the wt % loading of this acid is from about 1.00 wt % to about 6.00 wt %. In another aspect of this embodiment the wt % is from about 1.50 wt % to about 5.00 wt %. In another aspect of this embodiment the wt % is from about 1.50 wt % to about 4.00 wt %. In another aspect of this embodiment the wt % is from about 1.75 wt % to about 3.00 wt %. In another aspect of this embodiment the wt % is from about 1.80 wt % to about 2.75 wt %. In another aspect of this embodiment the wt % is from about 1.90 wt % to about 2.50 wt %. In another aspect of this embodiment the wt % is from about 1.90 wt % to about 2.30 wt %. In another aspect of this embodiment the wt % is from about 1.90 wt % to about 2.20 wt %. In another aspect of this embodiment the wt % is about 2 wt %. In another aspect of this embodiment, the sulfosalicylic acid may be one having structure (Ib) (or its hydrate). In another aspect of this embodiment, the sulfosalicylic acid may be one having structure (Ic) (or its hydrate). In another aspect of this embodiment, the sulfosalicylic acid may be one having structure (Id) (or its hydrate).

In one embodiment of the compositions described herein said primary solvent is acetone

In one embodiment of the compositions described herein said primary solvent is methyl ethyl ketone.

In one embodiment of the compositions described herein said primary solvent is a mixture of acetone and methyl ethyl ketone. In one aspect of this embodiment the wt % of acetone in the primary solvent mixture ranges from about 1 wt % to about 99.5 wt %. In one aspect of this embodiment no secondary glycolic derivative solvent component is present in the composition. In another aspect of this embodiment a secondary glycolic derivative solvent component is also is also present. In another aspect of this primary solvent mixture it contains about 95 wt % acetone. In another aspect this primary solvent mixture it contains about 90 wt % acetone. In yet another aspect of this primary solvent mixture it contains about 85 wt % acetone. In yet another aspect of this primary solvent mixture it contains about 80 wt % acetone. In yet another aspect of this embodiment this primary solvent mixture it contains about 75 wt % acetone. In yet another aspect of this primary solvent mixture it contains about 65 wt % acetone. In yet another aspect of this primary solvent mixture it contains about 60 wt % acetone. In yet another aspect of this primary solvent mixture it contains about 55 wt % acetone. In yet another aspect of this primary solvent mixture it contains about 50 wt % acetone. In yet another aspect of this primary solvent mixture it contains about 45 wt % acetone. In yet another aspect of this primary solvent mixture it contains about 40 wt % acetone. In yet another aspect of this primary solvent mixture, it contains about 35 wt % acetone. In yet another aspect of this primary solvent mixture, it contains about 30 wt % acetone. In yet another aspect of this primary solvent mixture, it contains about 25 wt % acetone. In yet another aspect of this primary solvent mixture, it contains about 20 wt % acetone. In yet another aspect of this primary solvent mixture, it contains about 15 wt % acetone. In yet another aspect of this primary solvent mixture, it contains about 10 wt % acetone. In yet another aspect of this primary solvent mixture it contains about 5 wt % acetone.

In embodiments of the composition described herein which contain a secondary glycolic derivative solvent component, this secondary glycolic derivative solvent component is either a single secondary glycolic derivative solvent or from a mixture of at least two of these types of solvents. This secondary glycolic derivative solvent component is present from about 1 wt % to about 30 wt % of the combined primary solvent and secondary glycolic derivative solvent components. In one embodiment it is about 1 wt % of the combined solvent components. In another embodiment, it is about 2 wt % of the combined solvent components. In another embodiment, it is about 3 wt % of the combined solvent components. In another embodiment, it is about 4 wt % of the combined solvent components. In another embodiment, it is about 5 wt % of the combined solvent components. In another embodiment, it is about 6 wt % of the combined solvent components. In another embodiment, it is about 7 wt % of the combined solvent components. In another embodiment, it is about 8 wt % of the combined solvent components. In another embodiment, it is about 9 wt % of the combined solvent components. In another embodiment, it is about 10 wt % of the combined solvent components. In another embodiment, it is about 11 wt % of the combined solvent components. In another embodiment, it is about 12 wt % of the combined solvent components. In another embodiment, it is about 13 wt % of the combined solvent components. In another embodiment, it is about 14 wt % of the combined solvent components. In another embodiment, it is about 15 wt % of the combined solvent components. In another embodiment, it is about 16 wt % of the combined solvent components. In another embodiment, it is about 17 wt % of the combined solvent components. In another embodiment, it is about 18 wt % of the combined solvent components. In another embodiment, it is about 19 wt % of the combined solvent components. In another embodiment, it is about 20 wt % of the combined solvent components. In another embodiment, it is about 21 wt % of the combined solvent components. In another embodiment, it is about 23 wt % of the combined solvent components. In another embodiment, it is about 23 wt % of the combined solvent components. In another embodiment, it is about 24 wt % of the combined solvent components. In another embodiment, it is about 25 wt % of the combined solvent components. In another embodiment, it is about 26 wt % of the combined solvent components. In another embodiment, it is about 27 wt % of the combined solvent components. In another embodiment, it is about 28 wt % of the combined solvent components. In another embodiment, it is about 29 wt % of the combined solvent components. In another embodiment, it is about 30 wt % of the combined solvent components.

In another aspect of these embodiments said secondary glycolic derivative solvent component is selected from an alkylenediols, an oligo(alkyleneoxyalkylene) diols [HO-(alkylene-O-alkylene-O)n-H] (n=1 to 4), monoalkyl ethers of alkylenediols, monoalkyl ethers of oligo(alkyleneoxyalkylene) diols, dialkyl ethers of alkylenediols, dialkyl ethers of oligo(alkyleneoxyalkylene) diols, alkylenediols in which one of the hydroxy groups is functionalized as an alkylcarboxylate and the other is functionalized as an ether, oligo(alkyleneoxyalkylene) diols in which one of the hydroxy groups is functionalized as an alkylcarboxylate and the other is functionalized as an ether, alkylenediols in which one of the hydroxy groups is functionalized as an alkylcarboxylate, oligo(alkyleneoxyalkylene) diols in which one of the hydroxy groups is functionalized as an alkylcarboxylate, alkylenediols in which both of the hydroxy groups are functionalized as alkylcarboxylates, oligo(alkyleneoxyalkylene) diols in which both of the hydroxy groups is functionalized as alkylcarboxylates, or is selected from a mixture of at least two of these solvent types.

In another aspect of these embodiments said secondary glycolic derivative solvent component is an alkanediol.

In another aspect of these embodiments said secondary glycolic derivative solvent component is an oligo(alkyleneoxyalkylene) diols [HO-(alkylene-O-alkylene-O)n-H] (n=1 to 4).

In another aspect of these embodiments said secondary glycolic derivative solvent component is a monoalkyl ether of an alkanediol.

In another aspect of these embodiments said secondary glycolic derivative solvent component is a monoalkyl ether of an oligo(alkyleneoxyalkylene) diols [HO-(alkylene-O-alkylene-O)n-H] (n=1 to 4).

In another aspect of these embodiments said secondary glycolic derivative solvent component is a is a dialkyl ether of an alkanediol.

In another aspect of these embodiments said secondary glycolic derivative solvent component is a dialkyl ether of an oligo(alkyleneoxyalkylene) diols [HO-(alkylene-O-alkylene-O)n-H] (n=1 to 4).

In another aspect of these embodiments said secondary glycolic derivative solvent component is an alkanediol in which one hydroxy group is functionalized as an alkyl ether and the other hydroxy group is functionalized as an alkyl carboxylate.

In another aspect of these embodiments said secondary glycolic derivative solvent component is an oligo(alkyleneoxyalkylene) diols [HO-(alkylene-O-alkylene-O)n-H] (n=1 to 4) in which one hydroxy is functionalized as an alkyl ether and the other hydroxy is functionalized as an alkylcarboxylate.

In another aspect of these embodiments said secondary glycolic derivative solvent component is a an alkylenediol in which one of the hydroxy groups is functionalized as an alkylcarboxylate.

In another aspect of these embodiments said secondary glycolic derivative solvent component is an oligo(alkyleneoxyalkylene) diols [HO-(alkylene-O-alkylene-O)n-H] (n=1 to 4) in which one of the hydroxy groups is functionalized as an alkylcarboxylate.

In another aspect of these embodiments said secondary glycolic derivative solvent is an alkylenediol in which both hydroxy groups are functionalized as an alkylcarboxylates.

In another aspect of these embodiments said secondary glycolic derivative solvent component is an oligo(alkyleneoxyalkylene) diols [HO-(alkylene-O-alkylene-O)n-H] (n=1 to 4) in which both hydroxy groups are functionalized as an alkylcarboxylates.

In another aspect of these embodiments said secondary glycolic derivative solvent component is a oligo(alkyleneoxyalkylene) diols [HO-(alkylene-O-alkylene-O)n-H] (n=1 to 4)

Ina more specific embodiment of said secondary glycolic derivative solvent component the alkylene moieties are selected from a be a C-2 to C-6 linear alkylene, or a C-3 to C-7 branched alkylene or in the case of the oligo oligo(alkyleneoxyalkylene) diols a mixture of these. In a more specific embodiment, the alkylene moiety is an C-3 alkylene.

Ina more specific embodiment of said secondary glycolic derivatives in which hydroxy groups are functionalized as alkyl ethers either as a monoalkyl ethers or as dialkyl ether the alkyl group are individually selected from methyl ethyl, propyl, isopropyl, butyl, tertbutyl, isobutyl.

Ina more specific embodiment of said secondary glycolic derivatives which have a hydroxy group functionalized by an alkylcarboxylate these alkylcarboxylate are selected from acetate, propionate, isobutyrate, and butyrate.

In another specific embodiment of this aspect of the glycolic derivative solvent it is selected from ethylene glycol, propylene glycol, 1-methoxy-2-propanol acetate (PGMEA), 1-methoxy-2-propanol (PGME), dipropylene glycol monomethyl ether (II) which has the formula (CH₃O)C₃H₆OC₃H₆(OH) (CAS #34590-94-8), dipropylene glycol dimethyl ether (III) (DPGDME) (CAS #111109-77-4), and dipropylene glycol (IV) (CAS #25265-71-8 25265-71) or a mixture of at least two of these solvents. In a more specific aspect of this embodiment said secondary glycolic derivative solvent is ethylene glycol. In a more specific aspect of this embodiment said secondary glycolic derivative solvent is propylene glycol. In a more specific aspect of this embodiment said secondary glycolic derivative solvent is 1-methoxy-2-propanol acetate. In a more specific aspect of this embodiment said secondary glycolic derivative solvent is 1-methoxy-2-propanol. In a more specific aspect of this embodiment said secondary glycolic derivative solvent is dipropylene glycol monomethyl ether. In a more specific aspect of this embodiment said secondary glycolic derivative solvent is dipropylene glycol dimethyl ether (III).

The aforementioned dipropylene glycol monomethyl ether (II) secondary glycolic derivative solvent, is a complex mixture which comprises the following isomeric compounds: 1-(2-methoxypropoxy)-2-propanol (CAS 13429-07-7) (IIa); 1-(2-methoxy-1-methylethoxy)-2-propanol (CAS 20324-32-7)(IIb), 2-(2-methoxypropoxy)-1-propanol (CAS 13588-28-8)(IIc); 2-(2-(2-methoxypropoxy)-1-propanol (CAS 55956-21-3) (IId), and their optical isomers. In another embodiment of the inventive compositions described herein containing a secondary glycolic derivative solvent, these individual solvent or mixture of at least two of IIa to IId, (and their optical isomers) are the secondary glycolic derivative solvent.

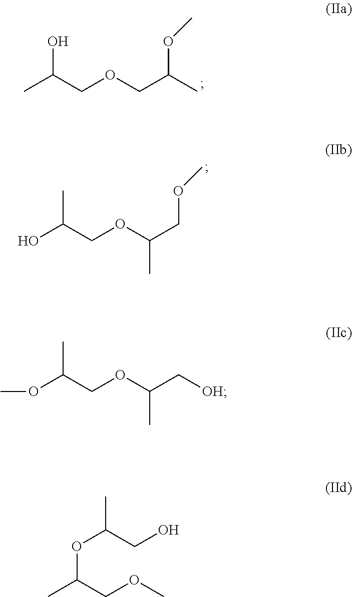

The aforementioned dipropylene glycol dimethyl ether (III) secondary glycolic derivative solvent is a complex mixture comprises the following isomeric compounds: 2-methoxy-1-(2-methoxypropoxy)propane (CAS #63019-84-1) (IIIa); 2-methoxy-1-((1-methoxypropan-2-yl)oxy)propane (CAS 89399-28-0) (IIIb), 2-methoxy-1-((1-methoxypropan-2-yl)oxy)propane (CAS #189354-80-1) (IIIc), having the following general structures IIIa, IIIb, and IIIc, and their optical isomers. In another embodiment of the inventive compositions described herein containing a secondary glycolic derivative solvent, these individual solvent or mixture of at least two of IIIa to IIIc, (and their optical isomers) are the secondary glycolic derivative solvent.

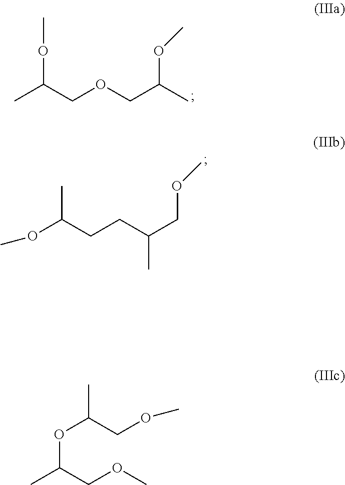

The aforementioned dipropylene glycol monomethyl ether (IV) secondary glycolic derivative solvent, is a complex mixture which comprises the following isomeric compounds: Bis(2-hydroxypropyl) ether (CAS #110-98-5) (IVa); 2-(2-hydroxypropoxy)-1-propanol (CAS #106-62-7) (IVb), 2,2′-Oxybis[1-propanol] (CAS #189354-80-1) (IVc), having the following general structures IVa, IVb, and IVc, and their optical isomers. In another embodiment of the inventive compositions described herein containing a secondary glycolic derivative solvent, these individual solvent or mixture of at least two of IVa to IVc, (and their optical isomers) are the secondary glycolic derivative solvent.

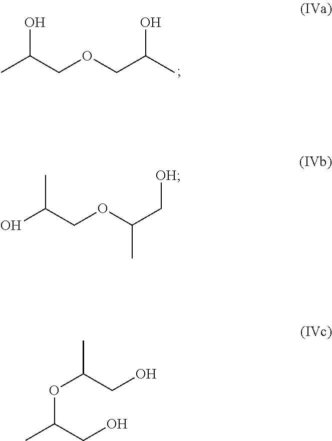

In the embodiment of the inventive composition described herein, containing a surfactant, there is no particular restriction with regard to the surfactant, and the examples of it include a polyoxyethylene alkyl ether such as polyoxyethylene lauryl ether, decaethylene glycol mono-dodecyl ether, polyoxyethylene stearyl ether, polyoxyethylene cetyl ether, and polyoxyethylene olein ether; a polyoxyethylene alkylaryl ether such as polyoxyethylene octylphenol ether and polyoxyethylene nonylphenol ether; a polyoxyethylene polyoxypropylene block copolymer; a sorbitane fatty acid ester such as sorbitane monolaurate, sorbitane monovalmitate, and sorbitane monostearate; a nonionic surfactant of a polyoxyethylene sorbitane fatty acid ester such as polyoxyethylene sorbitane monolaurate, polyoxyethylene sorbitane monopalmitate, polyoxyethylene sorbitane monostearate, polyethylene sorbitane trioleate, and polyoxyethylene sorbitane tristearate; a fluorinated surfactant such as F-Top EF301, EF303, and EF352 (manufactured by Jemco Inc.), Megafac F171, F172, F173, R08, R30, R90, and R94 (manufactured by Dainipponlnk & Chemicals, Inc.), Florad® FC-430, FC-431, FC-4430, and FC-4432 (manufactured by Sumitomo 3M Ltd.), Asahi Guard AG710, Surflon 5-381, 5-382, 5-386, SC101, SC102, SC103, SC104, SC105, SC106, Surfinol® E1004, KH-10, KH-20, KH-30, and KH-40 (manufactured by Asahi Glass Co., Ltd.); an organosiloxane polymer such as KP-341, X-70-092, and X-70-093 (manufactured by Shin-Etsu Chemical Co., Ltd.); and an acrylic acid or a methacrylic acid polymer such as Polyflow™ No. 75 and No. 95 (manufactured by Kyoeisha Yushikagaku Kogyo K. K.).

In another embodiment of the aforementioned inventive compositions the surfactant is present in an amount that is less than 1 wt % of the total weight of the composition. In another embodiment, the surfactant is present in an amount that is less than about 0.1 wt %.

In another embodiment of any of the above compositions the surfactant is a polymeric surfactant having structure (III), wherein n′″ is the number of, repeat units in the polymer and na is the number of CH₂ spacer moieties, which is an integer from 8 to 14. In another embodiment of this aspect of the composition said polymeric surfactant has structure (IIIa).

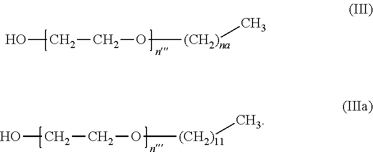

In embodiments of this invention are compositions containing a surfactant having structure (III) or (IIIa) each may individually be present in the composition from about 0.005 wt % to about 0.100 wt %. In another embodiment from about 0.010 wt % to about 0.050 wt %. In yet another embodiment from about 0.015 wt % to about 0.040 wt %. In still another embodiment from about 0.020 wt % to about 0.035 wt %. In yet another embodiment from about 0.022 wt % to about 0.030 wt %. In still another embodiment from about 0.023 wt % to about 0.028 wt %. In yet another embodiment from about 0.024 wt % to about 0.026 wt %. In still another embodiment about 0.025 wt %. In some of these embodiments, when a surfactant is present is further defined, as a surfactant corresponding to structure (III) or (IIIa), preferably no further surfactants different from these structures are present in the composition.

In one aspect of this invention one class of materials which can materially change the effectiveness of the remover because of particle deposition are specifically excluded from the inventive compositions described herein. Examples of these excluded materials are particles, pigment, dyes, antioxidants, and inhibitors of the rosin variety; such as, fumarated rosins and other materials which can form particles and deposit on the substrate during stripping.

In another aspect of this invention another class of materials which can materially change the effectiveness of the remover by causing corrosion on metal substrate are other acidic materials, having a pKₐ less than 5, which are specifically excluded from the inventive compositions described herein. Examples of these are sulfonic acids, other than those which are present in the inventive compositions described herein, having structure (I) (and substructures ((Ia), (Ib), (Ic), (Id)], non-limiting examples of such other types of sulfonic acid are arylsulfonic acids (e.g., benzenesulfonic acids, naphthalene sulfonic acids. alkylbenzensulfonic acids (e.g., tosic acid, dodecylbenzenesulfonic acid), alkylsulfonic acids (e.g., methanesulfonic acid, butanesulfonic acid), triflic acid, perfluoroalkylsulfonic acid (e.g., perfluorobutanesulfonic acid), partially fluorinatedalkylsulfonic acid (e.g., 2,2,2-trifluoroethanesulfonic acid), other arylsulfonic acids (substituted or unsubstituted e.g., benzenesulfonic acid, fluorobenzenesulfonic acids, di-fluorobenzenesulfonic acid, pentafluorobenzenesulfonic acid, propylbenzenesulfonic acid), nitrobenzenesulfonic acids, dinitrobenzenesufonic acids, benzenedisulfonic acids, and the like. Also excluded are sulfamic acids such as the non-limiting examples sulfamic acid, cyclamic acid, and methysulfamic acid. Also excluded are strong inorganic acids (pKₐ less than 0) such as the non-limiting examples, fluorosulfonic acid, nitric acid, sulfuric acid, hydrochloric acid and the like. Inorganic acids with a pKₐ more than 0, hydrofluoric acid, phosphorus oxoacids containing P in oxidation state +1 [e.g., H₃PO₂ (or H₂PO(OH)), hypophosphorous acid or phosphinic acid, a monoprotic acid]; phosphorus oxoacids containing P in oxidation state +3 [e.g., (H₃PO₃ (or HPO(OH)₂), phosphorous acid or phosphonic acid, a diprotic acid], Phosphorus oxoacids containing P in oxidation state +5 (e.g. Phosphoric acid:H₃PO₄ (or PO(OH)₃), Phosphoric acid, a tribasic acid phosphoric acid). Also excluded are carboxylic acid such as non-limiting examples of formic acid, alkylcarboxylic acids (e.g., acetic acid, propanoic acid and the like), perfluoroalkylcarboxylic acids (e.g., trifluoroacetic acid and the like), arylcarboxylic acids (e.g., benzoic acid and the like), alkylbenzenecarboxylic acids (e.g., toluic acid and the like), arylalkylenecarboxylic acid (e.g., phenylacetic acid, phenylpropanoic acid and the like), dicarboxylic acids (e.g., oxalic acid, maleic acid, malonic acid and the like), tricarboxylic acids (e.g., citric acid, isocitric acid, aconitic acid, propane-1,2,3-tricaboxylic acid, trimesic acid and the like). In another aspect of this embodiment other materials having a pKa less than 0 as described above are excluded from the stripper formulation. In one aspect of this embodiment other sulfonic acids having a pKa less than 0 are excluded from the formulation.

In another aspect of this invention both classes of materials which can materially change the effectiveness of the remover compositions by either causing particle deposition or by causing metal corrosion, as described individually herein in their different aspects, are excluded as components.

Another embodiment of this invention is a process comprising the steps;
i) thermally adjusting the temperature of any of the above described inventive compositions to be at a temperature which is from about 15° C. to about 80° C., resulting in a thermally adjusted composition,
ii) treating a substrate coated with a photoresist film with said thermally adjusted composition for a time from about 1 minutes to about 60 minutes, until a substrate with a removed photoresist film, results,
iii) after step ii), rinsing said substrate with one of isopropyl alcohol, a mixture isopropyl alcohol and water, or water to remove any residual composition from step ii), producing a clean substrate,
iv) drying said clean substrate.
   In a more specific embodiment of this process in step i) the composition is thermally adjusted to be about 20° C. to about 60° C. In another specific embodiment of this process in step i) the composition thermally adjusted to be about 20° C. to about 40° C. In yet another specific embodiment, in step ii), the substrate is a metal. In yet another specific embodiment, in step ii), the substrate is copper. In yet another specific embodiment, in step ii), the substrate is tin. In yet another specific embodiment, in step ii), the substrate is silver. In still another specific embodiment in step ii), the substrate is treated for about 1 minutes to about 20 minutes. In still another specific embodiment in step iii) the rinse is performed with a mixture of water and isopropanol which has a composition of water ranging from about 5 wt % to about 95 wt %.

In one embodiment of the above inventive process, said treating of said photoresist film which is removed in said step ii) it is one which is selected from the group consisting of a patterned photoresist film, a blanket exposed photoresist film having no pattern, and an unexposed photoresist film. In one embodiment it is a patterned photoresist film. In another embodiment it is an unexposed photoresist film. In another embodiment it is a blanket exposed photoresist film.

In one embodiment of the above inventive process, in step ii) said treating is done by either dipping it into said inventive composition, spraying with said thermally adjusted inventive composition or by puddling said thermally adjusted composition onto said photoresist film. In one aspect of this embodiment, dipping is used. In another aspect of this embodiment spraying is used. In another aspect of this embodiment puddling is used.

In another embodiment of the above inventive process in step i), the composition is thermally adjusted to be from about 30° C. to about 65° C.

In another embodiment of the above inventive process in step iv), said clean substrate is dried by either spin drying in air, using a stream of gas such as nitrogen, air, or some other inert gas, isopropyl alcohol (IPA) drying, or Marangoni Drying. In one aspect said drying is done by spin drying, In another aspect said drying is done by using said a stream of gas. In another aspect said drying is done by using IPA drying. In yet another aspect said drying is done by said Marangoni drying.

In one aspect of the above inventive process said photoresist film is a negative photoresist film.

In one aspect of the above inventive process said photoresist film is a positive photoresist film.

In another aspect of the any of the above inventive process said photoresist film is a chemically amplified photoresist film.

In another aspect of any of the above embodiment said photoresist film is a patterned negative photoresist film or a blanket exposed negative photoresist film. In one aspect it is a patterned negative photoresist film. In another aspect it is a blanket exposed negative photoresist film. In one aspect of these embodiments, said negative photoresist is a chemically amplified photoresist.

A patterned photoresist film as described herein refers to a photoresist film which has been exposed and developed with either an aqueous base developer or a solvent based developer to produced said patterned, said development may occur after a post-exposure bake depending on the type photoresist used to form the film.

A blanket exposed photoresist film refers to a photoresist film which has been exposed to radiation (e.g., i-line, g-line, UV, deep UV, broadband, EUV, e-beam and the like), but where no mask was used during the exposure to produce an exposed pattern, which upon development would produce a patterned photoresist film.

In another embodiment of the above inventive process in step ii) the substrate is a metal. In one aspect of this embodiment the metal is selected from copper, aluminum, aluminum/copper alloys, copper, silver, tin, titanium, tungsten and nickel. In another aspect of this embodiment of the process, the metal is selected from aluminum, aluminum/copper alloys, and copper. In still another embodiment of the above inventive process in step ii) the substrate is copper. In still another embodiment of the above inventive process in step ii), the substrate is tin.

In still another embodiment of the above inventive process in step ii) the substrate is substrate containing a bimetallic pattern which is comprised of two different metals selected from aluminum, aluminum/copper alloys, tin, silver and copper. In one aspect said bimetallic pattern is one of copper and tin. In another said bimetallic is silver and aluminum. In yet another said bimetallic pattern is of one of silver and an aluminum/copper alloy. In yet another embodiment said bimetallic pattern is one of silver and tin. In yet another embodiment said bimetallic pattern is one of silver and copper. In yet another embodiment said bimetallic pattern is one of silver and titanium. In yet another embodiment said bimetallic pattern is one of silver and tungsten. In yet another embodiment said bimetallic pattern is one of silver and nickel.

In another embodiment of the above inventive process in step ii) the substrate is treated for about 1 minutes to about 20 minutes. In another aspect of this embodiment in step ii) the substrate is treated for about 5 minutes to about 20 minutes.

In another embodiment of the above inventive process in step iii) the rinse is done with water.

The inventive remover composition may be used in the above inventive process to remove patterns from many different types of photoresist patterns as follows.

The inventive remover may be used to remove patterned resist films having a variety of thicknesses depending on the application, IC devices, IC devices interconnect, circuit board, solder board application, MEM, display and the like. Typically, the thickness tracts with the size of the device being manufactured starting from about tens of nanometers for state of the art IC, to the several microns range for larger IC devices, to 10 to 500 microns for very large devices such as MEM's.

The removers of the present disclosure can be used with resist pattern which arise from negative and positive photoresist material capable of forming patterns which may be selected from ones which may form patterns using different types of radiation. For instance, as non-limiting examples resist patterns for removal may be formed from i-line photoresists, g-line photoresists 248 nm photoresists, 193 nm photoresist, extreme ultraviolet photoresists, electron beam photoresists and particle beam photoresists. The removers of the present disclosure can be used with photoresist patterns may arise from photoresists which may be further classified as follows by the type of chemistry which is employed to obtain the pattern.

For instance, the removers of the present inventive compositions may be used to remove positive pattern resulting from, exposure by visible, i-line, h-line, and g-line and development by aqueous base employ of photoresists based upon a Novolak resin and a diazonaphthoquinone type sensitizer (DNQ) sensitizer material, these types of resist system may also yield negative images through a tone reversal process. Diazonapthoquinone-Novolak based resists are described in (Diazonapththoquinone-based Resists, Chapter 2, Basic Chemistry of DNQ/Novolak resists, SPIE Optional Engineering Press volume TT 11, page 9, 1993), which are hereby incorporated by reference in its entirety.

Also, the removers of the present inventive compositions can be used to remove resist films and patterns resulting from both negative or positive photoresist which are developable by either aqueous base or solvent.

Also, the removers of the present inventive compositions can be used to remove resist which are chemically amplified and aqueous base developable. Typically, resist patterns are formed by 248 nm, 193 nm, EUV to enable higher resolutions patterns, but resist patterns may also be produced using longer wavelengths, such as visible, broadband UV, i-line, g-line, and h-line.

The removers of the present disclosure can be used to remove resist patterns resulting from positive tone chemically amplified resists, resins which are latently aqueous base soluble, such as (meth)acrylate copolymers, styrenic copolymer, Novolaks, phenolic resins, are rendered aqueous base soluble by deprotecting acid cleavable group which mask aqueous base solubilizing moieties. The base solubilizing moieties may be carboxylic acids, phenols, or other moieties having typically a pKₐ below 11 such that aqueous base will largely ionize them. The acid is generated in exposed areas of the photoresist film by a photoacid generating compound. This acid deprotects the acid cleavable group through a process of acidolysis, or hydrolysis, releasing a free base solubilizing moiety, allowing, in exposed areas for the photoresist film to be aqueous base soluble.

The removers of the present disclosure can be used to remove resist patterns resulting from negative tone chemically amplified, whose inherent aqueous base solubility is not masked by any protecting group. Rather, in this approach, an inherently base soluble resin (binder resin) such as ones based on aqueous base soluble (meth)acrylate copolymers, styrenic copolymer, Novolaks, and the like are crosslinked catalytically by photo-acid through acid crosslinking moieties. These moieties may be pendent to the binder resins themselves, present on crosslinking additives (crosslinking agents) or present on both the resins and the additives. Acid catalyzed crosslinking in exposed areas is affected through a photo-acid generated by a PAG, which results, after aqueous base development in a negative tone image. Typically, when a crosslinking additive is employed it is a moiety capable of forming a carbonium ion upon interaction with the photoacid such as an aminoplast, or an additive containing acid crosslinkable group such as an epoxy compound. Similarly, if the crosslinking moiety is present on the resin it may either be a moiety capable of forming a carbonium ion with acid, or a moiety which can undergo crosslinking with an acid such as an epoxy moiety. The following reference is a review of chemically amplified resist: H. Ito, Adv Polym Sci, 2005, 172, p. 37.

The removers of the present disclosure can be used to remove resist patterns resulting from negative chemically amplified resist may result from negative chemically amplified resists, where the binder resins may comprise a Novolak, for instance ones derived from a substituted phenol such as ortho-cresol; meta-cresol; para-cresol; 2,4-xylenol; 2,5-xylenol; 3,4-xylenol, 3,5-xylenol, thymol and mixtures thereof, that has been condensed with an aldehyde such as formaldehyde. In other approaches, the binder resin may also comprise a poly(vinyl phenol) such as a poly(para-hydroxystyrene); a poly(para-hydroxy-alpha-methylstyrene; a copolymer of para-hydroxystyrene or para-hydroxy-alpha-methylstyrene and styrene, acetoxystyrene or acrylic acid and/or methacrylic acid; a hydroxyphenylalkyl carbinol homopolymer; or a Novolak/poly(vinyl phenol) copolymer. The crosslinking additives, for such negative chemically amplified resist, may be etherified aminoplast crosslinking functionalities containing within a small compound, an organic oligomer, or a polymer. Such aminoplasts, provide a carbonium ion, upon acid cleavage, and serves to crosslink the binder resin in the presence of an acid generated by radiation, preferably imaging radiation. This crosslinking renders the binder resin insoluble in an alkaline medium, in the exposed areas. Such crosslinking agents may be prepared from a variety of aminoplasts in combination with a compound or low molecular weight polymer containing a plurality of hydroxyl, carboxyl, amide or imide groups. Some examples of amino oligomers or polymers are aminoplasts obtained by the reaction of an amine, such as urea, melamine, or glycolurea with an aldehyde, such as formaldehyde. Suitable aminoplasts may include urea-formaldehyde, melamine-formaldehyde, benzoguanamine-formaldehyde, and gylcoluril-formaldehyde resins, and combinations of any of these. In some applications, the aminoplast is a hexa(methoxymethyl) melamine oligomer. A non-limiting example of such materials is described in U.S. Pat. No. 6,576,394.

### Examples

Reference will now be made to more specific embodiments of the present disclosure and experimental results that provide support for such embodiments. However, the applicants note that the disclosure below is for illustrative purposes only and is not intended to limit the scope of the claimed subject matter in any way.

### Chemicals

Photoresists products used in these examples AZ® nLOF 2070, AZ® 3DT, AZ® 4620, AZ® 15nXT were all obtained from EMD Performance Materials, Branchburg, NJ 08876. All other chemicals were purchased from Millipore Sigma (3050 Spruce St., St. Louis, MO 63103).

### Processing

For photoresist stripping tests, silicon wafers were used as the inorganic substrate upon which a chemically amplified negative photoresist AZ® nLOF 2070 (a product of EMD Performance Materials, Branchburg, NJ 08876) was applied and processed. The processing consisted of spin coating the resist to a desired thickness and applying a soft bake on a hotplate at 110° C. for 90 sec to form a 10 μm thick film. The resist was then exposed to 220 mJ/cm² of light through a contact hole patterned mask. A post-exposure bake was completed on a hotplate at 110° C. for 90 seconds before developing the resist. Development used AZ 300 MIF Developer in two puddles of 60 seconds each followed by a rinse with DI water.

Silicon 200 mm (8″) wafers with 150 nm silver sputter coating were used for silver corrosion testing. A silver coated silicon wafer coupon was immersed in a photoresist remover solution for a time of periods that were more than enough to strip a photoresist. Regular inspection was done to check the condition of the metal surface by visual and microscopic inspection for the presence of surface haze as indicative of corrosion. Surface haze can be identified and confirmed at levels more sensitive than gravimetric analysis (<10 Å/min).

### Silver Corrosion and Photoresist Stripping Test 1

A photoresist remover solution was prepared by dissolving 2 wt % 5-sulfosalicylic acid dihydrate (CAS: 5965-83-3) in acetone (CAS: 67-64-1). The room temperature solution was placed in a 150 ml beaker with a magnetic stirring bar (300 rpm). Silicon wafer coupon with AZ® nLOF 2070 photoresist patterns was immersed in the solution. The photoresist was dissolved within 20 second. The same solution and set-up were used for silver corrosion test. A silver wafer coupon was immersed in the solution for 60 minutes. The silver surface was free of haze and essentially intact by visual and microscopic inspections, and free of any particle deposition.

### Silver Corrosion and Photoresist Stripping Test 2

A photoresist remover solution was prepared by dissolving 2 wt % 5-sulfosalicylic acid dihydrate (CAS: 5965-83-3) in methyl ether ketone (CAS: 78-93-3). The room temperature solution was placed in a 150 ml beaker with a magnetic stirring bar (300 rpm). Silicon wafer coupon with AZ® nLOF 2070 photoresist patterns was immersed in the solution. The photoresist was dissolved within 20 seconds. The same solution and set-up were used for silver corrosion test. A silver wafer coupon was immersed in the solution for 60 minutes. The silver surface was free of haze and essentially intact by visual and microscopic inspections, and free of any particle deposition.

### Silver Corrosion and Photoresist Stripping Test 3

A photoresist remover solution was prepared by dissolving 2 wt % 5-sulfosalicylic acid dihydrate (CAS: 5965-83-3) in a mixture of acetone (CAS: 67-64-1) and di(propylene glycol) methyl ether (CAS: 34590-94-8) (weight ratio: 80:20). The room temperature solution was placed in a 150 ml beaker with a magnetic stirring bar (300 rpm). Silicon wafer coupon with AZ® nLOF 2070 photoresist patterns was immersed in the solution. The photoresist was dissolved within 20 seconds. The same solution and set-up were used for silver corrosion test. A silver wafer coupon was immersed in the solution for 60 minutes. The silver surface was free of haze and essentially intact by visual and microscopic inspections, and free of any particle deposition.

### Silver Corrosion and Photoresist Test 4

A photoresist remover solution was prepared by dissolving 10 wt % 5-sulfosalicylic acid dihydrate (CAS: 5965-83-3) in a mixture of acetone (CAS: 67-64-1) and di(propylene glycol) methyl ether (CAS: 34590-94-8) (weight ratio: 80:20). The room temperature solution was placed in a 150 ml beaker with a magnetic stirring bar (300 rpm). Silicon wafer coupon with AZ® nLOF 2070 photoresist patterns was immersed in the solution. The photoresist was dissolved within 20 seconds. The same solution and set-up were used for silver corrosion test. A silver wafer coupon was immersed in the solution for 60 minutes. The silver surface was free of haze and essentially intact by visual and microscopic inspections and free of any particle deposition.

### Silver Corrosion and Photoresist Test 5

A photoresist remover solution was prepared by dissolving 2 wt % 5-sulfosalicylic acid dihydrate (CAS: 5965-83-3) in a mixture of acetone (CAS: 67-64-1) and PGMEA (weight ratio: 80:20). The room temperature solution was placed in a 150 ml beaker with a magnetic stirring bar (300 rpm). Silicon wafer coupon with AZ® nLOF 2070 photoresist patterns was immersed in the solution. The photoresist was dissolved within 20 seconds. The same solution and set-up were used for silver corrosion test. A silver wafer coupon was immersed in the solution for 60 minutes. The silver surface was free of haze and essentially intact by visual and microscopic inspections and free of any particle deposition.

### Silver Corrosion and Photoresist Test 6

A photoresist remover solution was prepared by dissolving 2 wt % 5-sulfosalicylic acid dihydrate (CAS: 5965-83-3) in a mixture of acetone (CAS: 67-64-1) and PGME (weight ratio: 80:20) The room temperature solution was placed in a 150 ml beaker with a magnetic stirring bar (300 rpm). Silicon wafer coupon with AZ® nLOF 2070 photoresist patterns was immersed in the solution. The photoresist was dissolved within 20 seconds. The same solution and set-up were used for silver corrosion test. A silver wafer coupon was immersed in the solution for 60 minutes. The silver surface was free of haze and essentially intact by visual and microscopic inspections and free of any particle deposition.

### Silver Corrosion and Photoresist Test 7

photoresist remover solution was prepared by dissolving 2 wt % 5-sulfosalicylic acid dihydrate (CAS: 5965-83-3) in a mixture of acetone (CAS: 67-64-1) and propylene glycol (CAS number: 57-55-6) (weight ratio: 80:20). The room temperature solution was placed in a 150 ml beaker with a magnetic stirring bar (300 rpm). Silicon wafer coupon with AZ® nLOF 2070 photoresist patterns was immersed in the solution. The photoresist was dissolved within 20 seconds. The same solution and set-up were used for silver corrosion test. A silver wafer coupon was immersed in the solution for 60 minutes. The silver surface was free of haze and essentially intact by visual and microscopic inspections and free of any particle deposition.

### Silver Corrosion and Photoresist Test 8

A photoresist remover solution was prepared by dissolving 2 wt % 5-sulfosalicylic acid dihydrate (CAS: 5965-83-3) in a mixture of acetone (CAS: 67-64-1) and di(propylene glycol) dimethyl ether (CAS: 111109-77-4) (weight ratio: 80:20). The room temperature solution was placed in a 150 ml beaker with a magnetic stirring bar (300 rpm). Silicon wafer coupon with AZ® nLOF 2070 photoresist patterns was immersed in the solution. The photoresist was dissolved within 20 seconds. The same solution and set-up were used for silver corrosion test. A silver wafer coupon was immersed in the solution for 60 minutes. The silver surface was free of haze and essentially intact by visual and microscopic inspections and free of any particle deposition.

### Silver Corrosion and Photoresist Test 9

A photoresist remover solution was prepared by dissolving 10 wt % 5-sulfosalicylic acid dihydrate (CAS: 5965-83-3) in a mixture of acetone (CAS: 67-64-1) and propylene glycol (CAS: 57-55-6) (weight ratio: 80:20). The room temperature solution was placed in a 150 ml beaker with a magnetic stirring bar (300 rpm). Silicon wafer coupon with AZ® nLOF 2070 photoresist patterns was immersed in the solution. The photoresist was dissolved within 20 seconds. The same solution and set-up were used for silver corrosion test. A silver wafer coupon was immersed in the solution for 60 minutes. The silver surface was free of haze and essentially intact by visual and microscopic inspections, and free of any particle deposition.

### Stripping of Other Type of Photoresists

The Silver Corrosion and Photoresist Stripping Test 1 was done for other types of photoresists which all showed quick removal of thick photoresist films (20 seconds or less) without corrosion of metals such as silver or copper and also without deposition of particles as summarized in Table 1.

TABLE 1

| | | | | | Photoresist |
|---|---|---|---|---|---|
| | | | | | film completely |
| | Photoresist | Sub- | Hard | FT | dissolved in |
| Photoresist | Type | strate | Bake | (μm) | 20 secs or less |
| AZ ®3DT | Positive | Si | None | 12.6 | Yes |
| | Chemically | | | | |
| | amplified | | | | |
| AZ ®4620 | Positive | Si | None | 12.4 | Yes |
| | Novolak/DNQ | | | | |
| AZ ®15nXT | Negative | Cu | None | 11.0 | Yes |
| | Cross-linked | | | | |

### Comparative Photoresist Stripping Test 1

A photoresist remover solution was prepared by dissolving 2 wt % 5-sulfosalicylic acid dihydrate (CAS: 5965-83-3) in di(propylene glycol) methyl ether (CAS: 34590-94-8). The room temperature solution was placed in a 150 ml beaker with a magnetic stirring bar (300 rpm). Silicon wafer coupon with AZ® nLOF 2070 photoresist patterns was immersed in the solution. The photoresist dissolution took at least 20 min.

### Comparative Photoresist Stripping Test 2

A photoresist remover solution was prepared by dissolving 2 wt % 5-sulfosalicylic acid dihydrate (CAS: 5965-83-3) in 2-heptanone (CAS: 110-43-0). The room temperature solution was placed in a 150 ml beaker with a magnetic stirring bar (300 rpm). Silicon wafer coupon with AZ® nLOF 2070 photoresist patterns was immersed in the solution. The photoresist dissolution took at least 20 min.

### Comparative Photoresist Stripping Test 3

A photoresist remover solution was prepared by dissolving 2 wt % 5-sulfosalicylic acid dihydrate (CAS: 5965-83-3) in cyclohexanone (CAS: 108-94-1). The room temperature solution was placed in a 150 ml beaker with a magnetic stirring bar (300 rpm). Silicon wafer coupon with AZ® nLOF 2070 photoresist patterns was immersed in the solution. The photoresist dissolution took at least 20 min.

### Comparative Photoresist Stripping Test 4

A photoresist remover solution was prepared by dissolving 2 wt % 5-sulfosalicylic acid dihydrate (CAS: 5965-83-3) in di(propylene glycol) dimethyl ether (CAS: 111109-77-4). The room temperature solution was placed in a 150 ml beaker with a magnetic stirring bar (300 rpm). Silicon wafer coupon with AZ® nLOF 2070 photoresist patterns was immersed in the solution. The photoresist dissolution took at least 20 min.

### Comparative Metal Corrosion Test 1

A photoresist remover solution was prepared by dissolving 2 wt % dodecylbenzenesulfonic acid (CAS: 68584-22-5) in acetone. The solution was put in a 150 ml beaker with a magnetic stirring bar (300 rpm). A silver wafer coupon was immersed in the solution. After 5 minutes, the silver layer on silicon wafer turned hazy indicating corrosion.

We claim:

1. A composition consisting essentially of
one of at least one sulfosalicylic acids having structure (I), its hydrate, or a mixture of this sulfosalicylic acid and its hydrate;
a primary solvent selected from acetone, and methyl ethyl ketone, or a mixture of these solvents,
a secondary solvent which is a glycolic derivative, or a mixture of at least two glycolic derivatives, and
an optional surfactant;

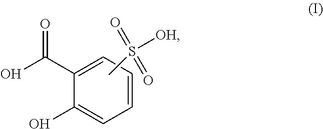

2. The composition of claim 1 consisting of
one of at least one sulfosalicylic acids having structure (I), its hydrate, or a mixture of this sulfosalicylic acid and its hydrate;
a primary solvent selected from acetone, and methyl ethyl ketone, or a mixture of these solvents,
a secondary solvent which is a glycolic derivative, or a mixture of at least two glycolic derivatives, and

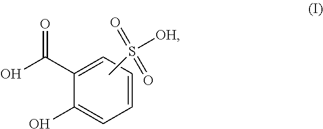

3. The composition of claim 1, consisting essentially of
one of at least one sulfosalicylic acid having structure (I), its hydrate, or a mixture of this sulfosalicylic acid and its hydrate;
a primary solvent selected from acetone, and methyl ethyl ketone, or a mixture of these solvents; and a secondary solvent which is a glycolic derivative, or a mixture of at least two glycolic derivatives.

4. The composition of claim 1, consisting of
one of at least one sulfosalicylic acid having structure (I), its hydrate, or a mixture of this sulfosalicylic acid and its hydrate;
a primary solvent selected from acetone, and methyl ethyl ketone, or a mixture of these solvents; and a secondary solvent which is a glycolic derivative, or a mixture of at least two glycolic derivatives.

5. The composition of claim 1 consisting essentially of
one of at least one sulfosalicylic acid having structure (I), its hydrate, or a mixture of this sulfosalicylic acid and its hydrate,
a primary solvent selected from acetone, and methyl ethyl ketone, or a mixture of these solvents, and a secondary solvent which is a glycolic derivative, or a mixture of at least two glycolic derivatives, and a surfactant.

6. The composition of claim 1 consisting of
one of at least one sulfosalicylic acid having structure (I), its hydrate, or a mixture of this sulfosalicylic acid and its hydrate,
a primary solvent selected from acetone, and methyl ethyl ketone, or a mixture of these solvents, and a secondary solvent which is a glycolic derivative, or a mixture of at least two glycolic derivatives, and a surfactant.

7. The composition of claim 1, wherein said sulfosalicylic acid is one having structure (Ia) or its hydrate:

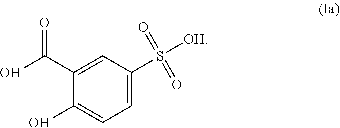 [SMILES: O=C(O)c1cc(S(=O)(=O)O)ccc1O]

8. The composition of claim 1, wherein said sulfosalicylic acid is one having structure (Ib) or its hydrate:

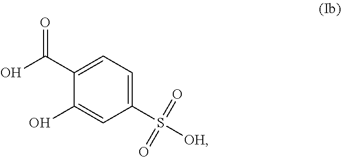 [SMILES: O=C(O)c1ccc(S(=O)(=O)O)cc1O]

9. The composition of claim 1, wherein said sulfosalicylic acid is one having structure (Ic) or its hydrate:

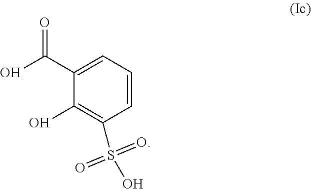 [SMILES: O=C(O)c1cccc(S(=O)(=O)O)c1O]

10. The composition of claim 1, wherein said sulfosalicylic acid is one having structure (Id) or its hydrate:

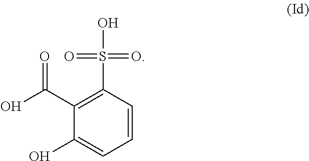 [SMILES: O=C(O)c1c(O)cccc1S(=O)(=O)O]

11. The composition of claim 1, wherein said primary solvent is acetone.

12. The composition of claim 1, wherein said primary solvent is methyl ethyl ketone.

13. The composition of claim 1, wherein said primary solvent is a mixture of acetone and methyl ethyl ketone.

14. The composition of claim 1, wherein said secondary solvent is selected from the group consisting alkylenediols, oligo(alkyleneoxyalkylene) diols [HO-(alkylene-O-alkylene-O)n-H] (n=1 to 4), monoalkyl ethers of alkylenediols, monoalkyl ethers of oligo(alkyleneoxyalkylene) diols, dialkyl ethers of alkylenediols, dialkyl ethers of oligo(alkyleneoxyalkylene) diols, alkylenediols in which one of the hydroxy groups is functionalized as an alkylcarboxylate and the other is functionalized as an ether, oligo(alkyleneoxyalkylene) diols in which one of the hydroxy groups is functionalized as an alkylcarboxylate and the other is functionalized as an ether, alkylenediols in which one of the hydroxy groups is functionalized as an alkylcarboxylate, oligo(alkyleneoxyalkylene) diols in which one of the hydroxy groups is functionalized as an alkylcarboxylate, alkylenediols in which both of the hydroxy groups are functionalized as alkylcarboxylates, oligo(alkyleneoxyalkylene) diols in which both of the hydroxy groups is functionalized as alkylcarboxylates.

15. The composition of claim 14, wherein said secondary solvent is an alkanediol.

16. The composition of claim 14, wherein said secondary solvent is an oligo(alkyleneoxyalkylene) diols [HO-(alkylene-O-alkylene-O)n-H] (n=1 to 4).

17. The composition of claim 14, wherein said secondary solvent is a monoalkyl ether of an alkanediol.

18. The composition of claim 14, wherein said secondary solvent is a monoalkyl ether of an oligo(alkyleneoxyalkylene) diols [HO-(alkylene-O-alkylene-O)n-H] (n=1 to 4),

19. The composition of claim 14, wherein said secondary solvent is a dialkyl ether of an alkanediol.

20. The composition of claim 14, wherein said secondary solvent is a dialkyl ether of an oligo(alkyleneoxyalkylene) diols [HO-(alkylene-O-alkylene-O)n-H] (n=1 to 4).

21. The composition of claim 14, wherein said secondary solvent is of an alkanediol in which one hydroxy group is functionalized as an alkyl ether and the other hydroxy group is functionalized as an alkyl carboxylate.

22. The composition of claim 14, wherein said secondary solvent is an oligo(alkyleneoxyalkylene) diols [HO-(alkylene-O-alkylene-O)n-H] (n=1 to 4) in which one hydroxy is functionalized as an alkyl ether and the other hydroxy is functionalized as an alkylcarboxylate.

23. The composition of claim 14, wherein said secondary solvent is a an alkylenediol in which one of the hydroxy groups is functionalized as an alkylcarboxylate.

24. The composition of claim 14, wherein said secondary solvent is an oligo(alkyleneoxyalkylene) diols [HO-(alkylene-O-alkylene-O)n-H] (n=1 to 4) in which one of the hydroxy groups is functionalized as an alkylcarboxylate.

25. The composition of claim 14, wherein said secondary solvent is an alkylenediol in which both hydroxy groups are functionalized as an alkylcarboxylates.

26. The composition of claim 14, wherein said secondary solvent is an oligo(alkyleneoxyalkylene) diols [HO-(alkylene-O-alkylene-O)n-H] (n=1 to 4) in which both hydroxy groups are functionalized as an alkylcarboxylates.

27. The composition of claim 1, wherein said secondary solvent is selected from either a solvent selected from the group consisting of PGME, PGMEA, propylene glycol, dipropylene glycol (IV), dipropylene glycol mono methyl ether (II), dipropylene mono methyl ether (Ill), or a mixture of at least two of these solvents.

28. The composition of claim 30, wherein said secondary solvent is dipropylene glycol mono methyl ether (II).

29. A composition consisting essentially of
one of at least one sulfosalicylic acids having structure (I), its hydrate, or a mixture of this sulfosalicylic acid and its hydrate;
a primary solvent selected from acetone, and methyl ethyl ketone, or a mixture of these solvents,
optionally a secondary solvent which is a glycolic derivative, or a mixture of at least two glycolic derivatives, and
optionally a surfactant; 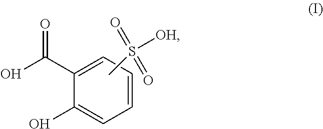
wherein the sulfosalicylic acid of structure (I) or its hydrate is selected from ones having structures (Ib), (Ic), (Id) or its hydrate, mixtures thereof, and mixtures thereof with ones having structure (Ia) or its hydrate

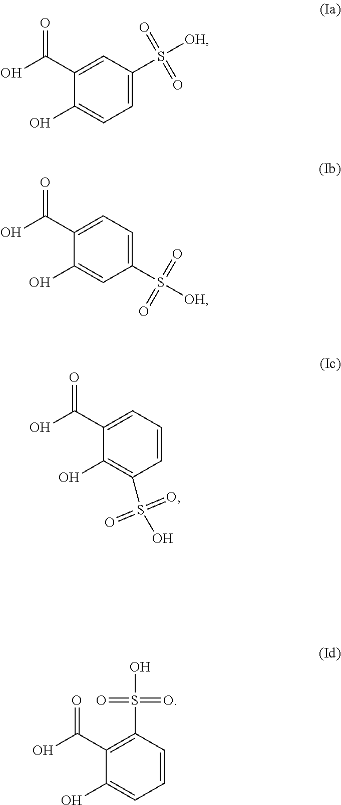 [SMILES: O=C(O)c1cc(S(=O)(=O)O)ccc1O ; O=C(O)c1ccc(S(=O)(=O)O)cc1O ; O=C(O)c1cccc(S(=O)(=O)O)c1O ; O=C(O)c1c(O)cccc1S(=O)(=O)O]

30. The composition of claim 29 consisting of
one of at least one sulfosalicylic acids having structure (I), its hydrate, or a mixture of this sulfosalicylic acid and its hydrate;
a primary solvent selected from acetone, and methyl ethyl ketone, or a mixture of these solvents,
optionally a secondary solvent which is a glycolic derivative, or a mixture of at least two glycolic derivatives, and
optionally a surfactant; 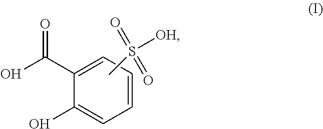
wherein the sulfosalicylic acid of structure (I) or its hydrate is selected from ones having structures (Ib), (Ic), (Id) or its hydrate, mixtures thereof, and mixtures thereof with ones having structure (Ia) or its hydrate

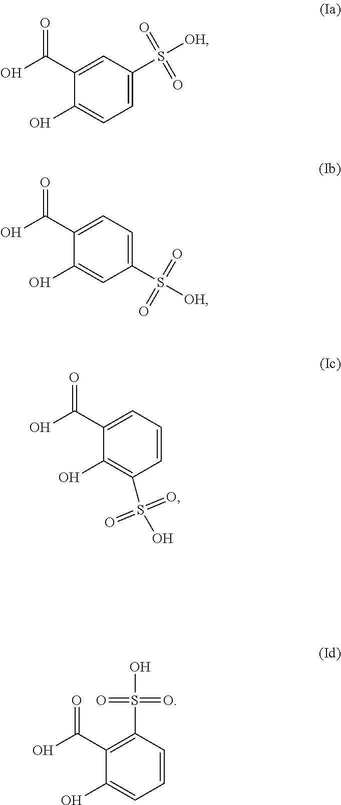 [SMILES: O=C(O)c1cc(S(=O)(=O)O)ccc1O ; O=C(O)c1ccc(S(=O)(=O)O)cc1O ; O=C(O)c1cccc(S(=O)(=O)O)c1O ; O=C(O)c1c(O)cccc1S(=O)(=O)O]

31. A process comprising the steps:
i) thermally adjusting a composition consisting essentially of
one of at least one sulfosalicylic acids having structure (I), its hydrate, or a mixture of this sulfosalicylic acid and its hydrate;
a primary solvent selected from acetone, and methyl ethyl ketone, or a mixture of these solvents,
an optional secondary solvent which is a glycolic derivative, or a mixture of at least two glycolic derivatives, and
an optional surfactant; 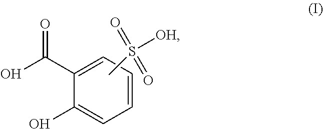
to be at a temperature of about 15° C. to about 80° C., resulting in a thermally adjusted composition
ii) treating a substrate coated with a photoresist film with said thermally adjusted composition for a time from about 1 minutes to about 60 minutes, until a substrate with a removed photoresist film, results,
iii) after step ii), rinsing said substrate with a removed photoresist film with one of isopropyl alcohol, a mixture isopropyl alcohol and water, or water to remove any residual composition from step ii), producing a clean substrate,
iv) drying said clean substrate.

32. The process of claim 31, wherein, wherein, in said composition, said secondary solvent is present.

33.-41. (canceled)
